(19) United States
(12) Patent Application Publication
(10) Pub. No.: US 2005/0186764 A1
(43) Pub. Date: Aug. 25, 2005

(54) Method for lifting offGaN pseudomask epitaxy layerusing wafer bonding way

(75) Inventors: Yew-Chung Wu, Hsinchu (TW); Pei-Yen Lin, Hsinchu (TW); Hsien-Chih Peng, Hsinchu (TW)

Correspondence Address: TROXELL LAW OFFICE PLLC, SUITE 1404, 5205 LEESBURG PIKE, FALLS CHURCH, VA, 22041, US

(73) Assignee: National Chiao Tung University

(21) Appl. No.: 10/848,143

(22) Filed: May 19, 2004

Related U.S. Application Data
(63) Continuation-in-part of application No. 10/781,892, filed on Feb. 20, 2004.

(51) Int. Cl. H01L 21/00

(52) U.S. Cl. 438/479

(57) ABSTRACT

Present invention is a method for lifting off GaN pseudomask epitaxy layer using wafer bonding way, wherein GaN epitaxy is obtained by way of selective area growth on a seed and the growth is in a way of pseudomask growth over a substrate. Owing to the different thermal expansion coefficients of the substrate and the GaN seed, by way of annealing and wafer bonding, the GaN epitaxy layer and the epitaxy substrate can be separated, or the GaN epitaxy substrate can be transferred onto another substrate. Thereby, the epitaxy substrate separated is not spoiled during the transferring procedure and can be reused, which lowers the cost; and high-quality GaN epitaxy layer can be transferred to various kinds of substrates for various kinds of usage and for solving the problems of difficulties in the production or the utilization of the substrate (such as difficulties in the cutting, the conductivity, the heat-sinking, and so on.)

### RELATED APPLICATION

This application is a Continuation-In-Part of application Ser. No. 10/781,892, filed on Feb. 20, 2004 and currently pending.

### FIELD OF THE INVENTION

Present invention relates to a method for lifting off GaN pseudomask epitaxy layer using wafer bonding way; more particularly, relates to a procedure improvement on producing GaN epitaxy to promote application and commercial mass production.

### DESCRIPTION OF RELATED ARTS

According to the GaN technology, because GaN is difficult to grow bulk material, there dose not exist a GaN epitaxial substrate and GaN needs to epitaxy on the substrate made by other material. Limited kinds of epitaxy substrates limit possibilities for application. The techniques used in separating GaN substrate include Laser Lift-Off and Smart Cut, wherein both are limited in application and have some defects. Besides, between the GaN epitaxy layer obtained and the substrate transferred onto is a buffer layer with some defects.

To sum up, the shortcomings of the related arts include the followings:

1. The epitaxy layer can be easily spoiled; the cost is high; and only specific scale of size is suitable.

2. The epitaxy substrate separated will be spoiled during etching procedure and will not be reusable.

3. The kinds of substrates for transference tend to be limited by the epitaxy.

4. The epitaxy layer transferred has dense defects that, when applying to the components, the period of use can not be prolonged and the efficiency can not be increased.

5. Expansive equipments are required in the processes of the related arts so that the production cost is increased.

Accordingly, the methods of the related arts for lifting off GaN epitaxy layer from the substrate do not fulfill users' requests.

### BRIEF DESCRIPTION OF THE INVENTION

Therefore, the purpose of the present invention is to obtain a good-quality GaN epitaxy layer and to transfer it to a selective substrate, wherein different kinds of substrates provide different kinds of usage. At the same time, the present invention is to solve the problems of difficulties in the cutting, the conductivity, the cost, the heat-sinking, and so on, of the substrate.

Another purpose of the present invention is to provide a method of combining the procedure of obtaining GaN epitaxy layer by pseudomask overgrowth and the procedure of wafer bonding, to transfer onto another substrate and to gain more additional advantages by such a combination. At the same time, the present invention is to solve the problems of difficulties in the cutting, the conductivity, the cost, the heat-sinking, and so on, of the GaN epitaxy substrate.

The third purpose of the present invention is to invent a new technique for substrate transference so that the current techniques of Laser Lift-Off and Smart Cut can be superseded and the product of large scale and the commercial mass production are possible.

The fourth purpose of the present invention is that the epitaxy layer lifted off can be used as a GaN epitaxy substrate with better quality.

To achieve the above purposes, the present invention is a method for lifting off GaN pseudomask epitaxy layer using wafer bonding way, comprising the following steps: 1) to obtain a substrate and deposit a low-temperature buffer layer on it; 2) to deposit a GaN layer after heating up the buffer layer; 3) to deposit a layer of mask material on the buffer layer; 4) to make an opening by way of lithography technique on the layer of mask material; 5) to etch GaN for obtaining a seed for GaN to grow upon; 6) to apply GaN pendeoepitaxy lateral overgrowth to the sample etched; and, 7) through proper washing and proper plating with metal or plating with glue, to obtain a substrate for transference and then to apply direct or indirect wafer bonding to the above sample. Accordingly, a method for lifting off GaN pseudomask epitaxy layer using wafer bonding way is obtained.

### DESCRIPTION OF THE DRAWINGS

FIG. 1 is a view of step 1 of the first preferred embodiment according to the present invention;

FIG. 2 is a view of step 2 of the first preferred embodiment according to the present invention;

FIG. 3 is a view of step 3 of the first preferred embodiment according to the present invention;

FIG. 4 is a view of step 4 of the first preferred embodiment according to the present invention;

FIG. 5 is a view of step 5 of the first preferred embodiment according to the present invention;

FIG. 6 is a view of step 6 of the first preferred embodiment according to the present invention;

FIG. 7 is a view of step 7 of the first preferred embodiment according to the present invention;

FIG. 8 is a view of step 8 of the first preferred embodiment according to the present invention;

FIG. 9 is a view of step 9 of the second preferred embodiment according to the present invention;

FIG. 10 is a view of step 10 of the second preferred embodiment according to the present invention;

FIG. 11 is a view of step 11 of the second preferred embodiment according to the present invention;

FIG. 12 is a view of step 12 of the second preferred embodiment according to the present invention;

FIG. 13 is a view of step 13 of the second preferred embodiment according to the present invention;

FIG. 14 is a view of step 14 of the second preferred embodiment according to the present invention;

FIG. 15 is a view of step 15 of the third preferred embodiment according to the present invention;

FIG. 16 is a view of step 16 of the third preferred embodiment according to the present invention;

FIG. 17 is a view of step 17 of the third preferred embodiment according to the present invention;

FIG. 18 is a view of step 18 of the third preferred embodiment according to the present invention;

### DESCRIPTION OF THE PREFERRED EMBODIMENTS

The following descriptions of the preferred embodiment are provided to understand the features and the structures of the present invention.

The present invention is a method for lifting off GaN pseudomask epitaxy layer using wafer bonding way, wherein the base substrate on which GaN is transferred and separated will not be spoiled and is reusable; and wherein a stress concentration is produced on the contact between the substrate and the seed during wafer bonding to separate them owing to different thermal expansion coefficients.

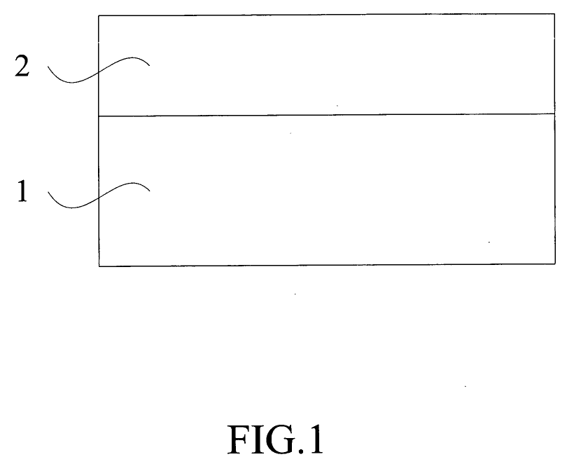

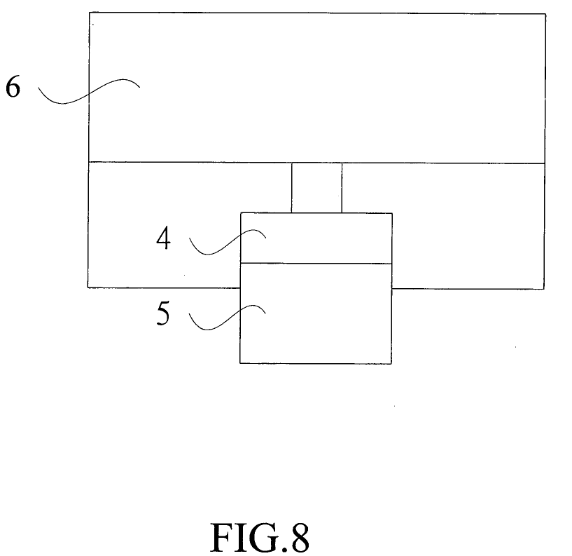

Please refer to FIG. 1 to FIG. 8, which are views of step 1 to step 8 of the first preferred embodiment according to the present invention. As shown in the figures, the following steps are comprised:

Step 1: Obtain a base substrate 1 of sapphire, SiC, or silicon, and so on, and deposit a 200-500 angstroms of low-temperature buffer layer 2 of GaN or AIN on the base substrate 1 on 600-700 Celsius degrees of temperature. (As shown in FIG. 1)

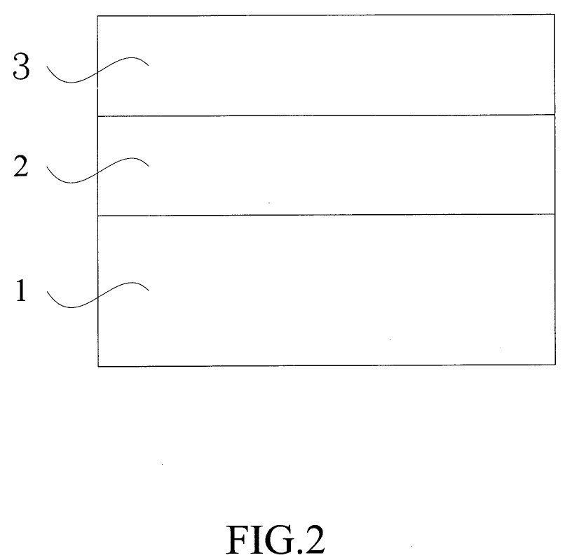

Step 2: Deposit another 1.5 μm-thick GaN 3 after the buffer layer 2 is heated up to 1000-1100 Celsius degrees of temperature. (As shown in FIG. 2)

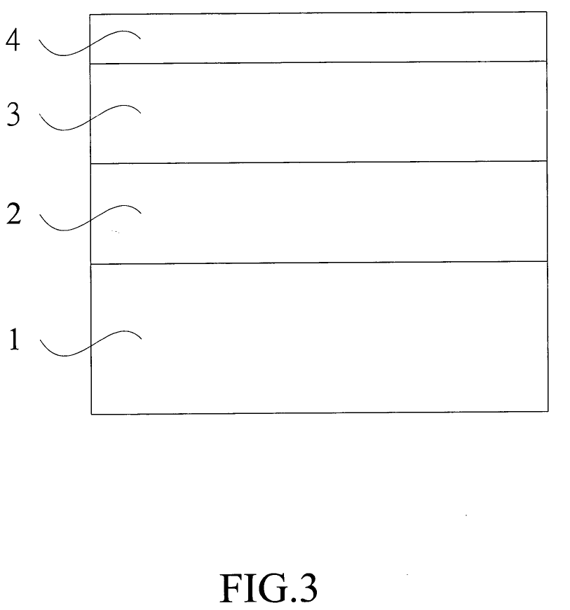

Step 3: Deposit a layer of mask material 4 of metal or ceramic like SiO2, Si3N4 or W on the low-temperature buffer layer 2. (As shown in FIG. 3)

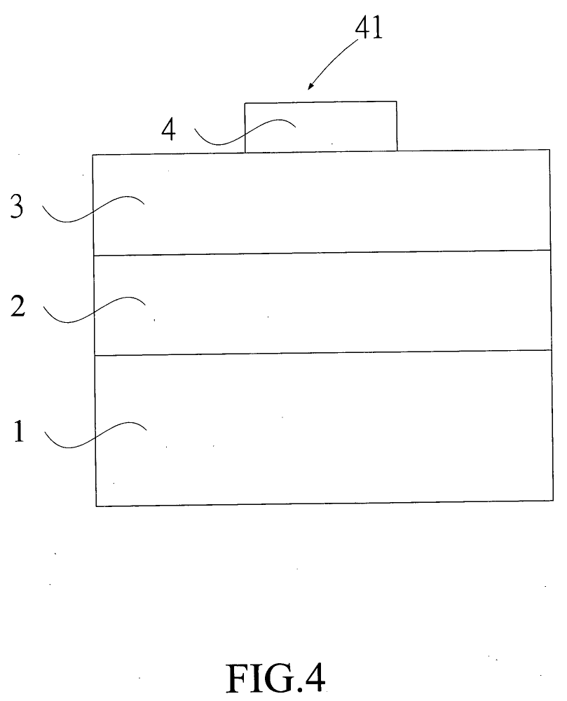

Step 4: Make an opening 41 in dot pattern or line pattern on the layer of mask material 4 by way of lithography technique. (As shown in FIG. 4)

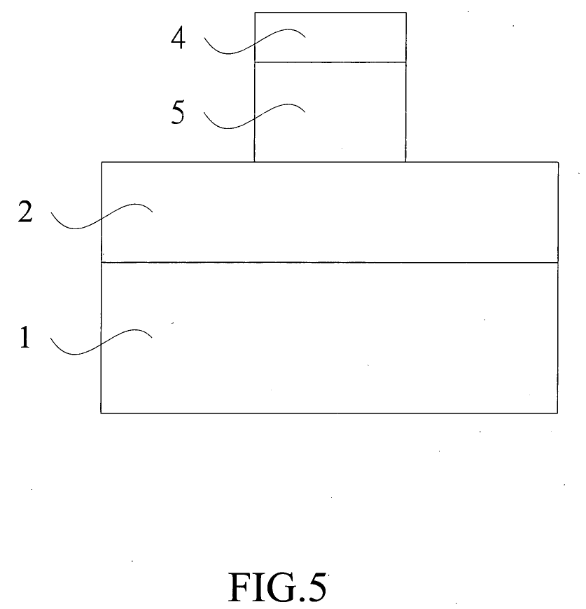

Step 5: Etch the GaN 3 to obtain a seed 5 for GaN to grow upon. (As shown in FIG. 5)

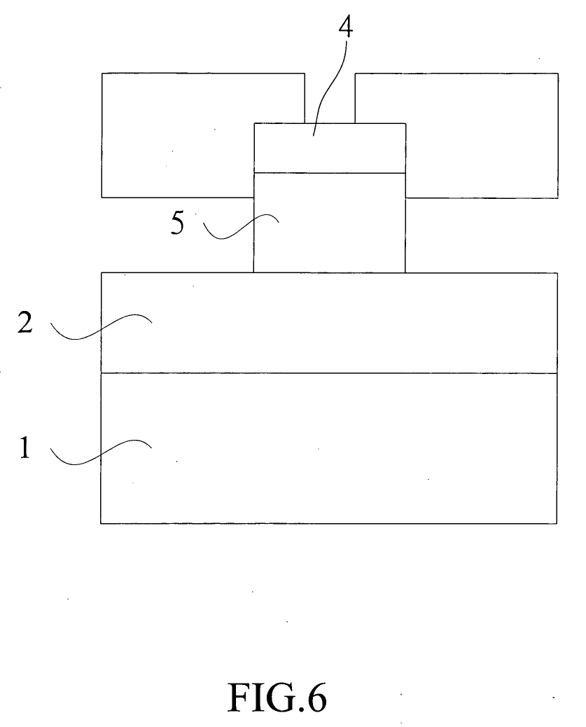

Step 6: Over the layer of mask material 4, apply GaN penrdeoepitaxy lateral overgrowth to the sample etched on 1000-1100 Celsius degrees of temperature. (As shown in FIG. 6)

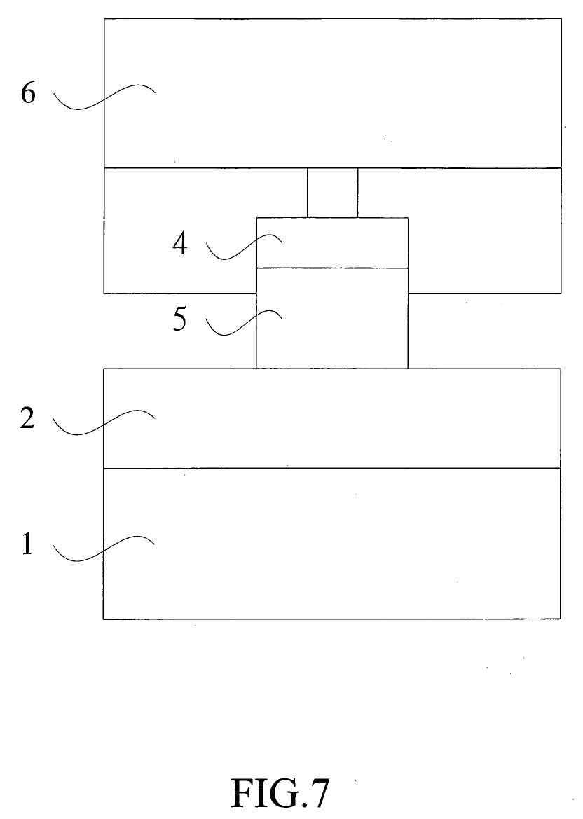

Step 7: Obtain a substrate for transference which can be made of Si. Through proper washing and proper plating with metal (such as gold, indium or palladium), apply wafer bonding to the above sample, wherein the temperature is determined by the material of the substrate for transference and the planted material. (As shown in FIG. 7)

Step 8: Separate the sample from the substrate for transference. (As shown in FIG. 7)

Accordingly, a method for lifting off GaN pseudomask epitaxy layer using wafer bonding way is obtained by the above steps.

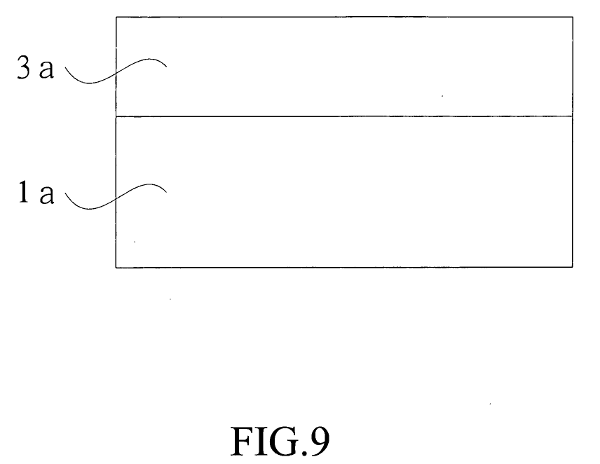

Please refer to FIG. 9 to FIG. 14, which are views of step 1 to step 6 of the second preferred embodiment according to the present invention. As shown in the figures, the following steps are comprised:

Step 1: Deposit a 1 μm-thick GaN 3a upon the base substrate 1a of sapphire, SiC or silicon. (As shown in FIG. 9)

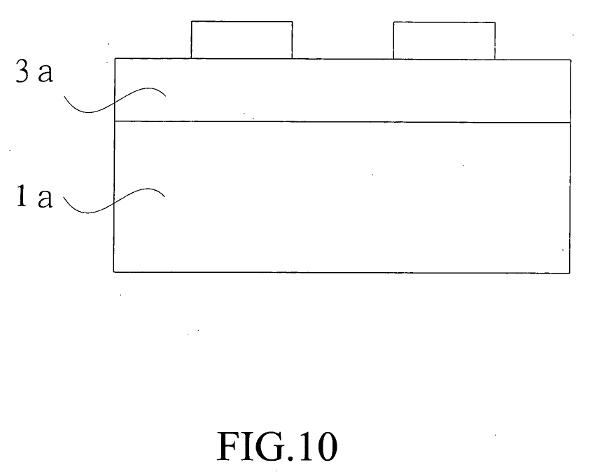

Step 2: Etch the GaN 3a of step 1 by way of lithography technique to obtain a GaN seed 5a in dot pattern or in line pattern. (As shown in FIG. 10)

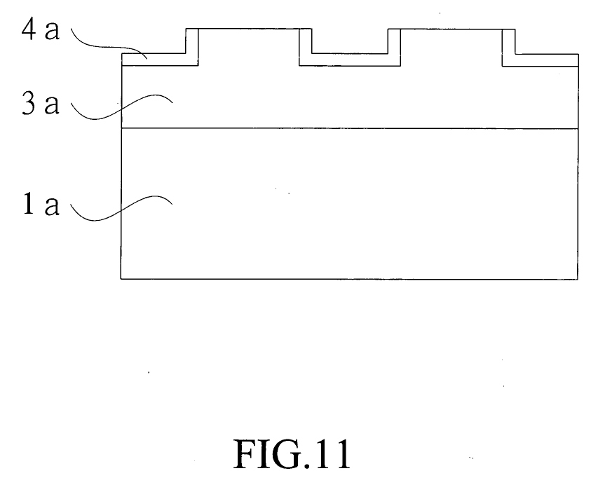

Step 3: On the area out of the GaN seed 5a, deposit a 100 angstroms of mask material 4a like SiN, W, or SiO2, and so on, by way of lithography technique. (As shown in FIG. 11)

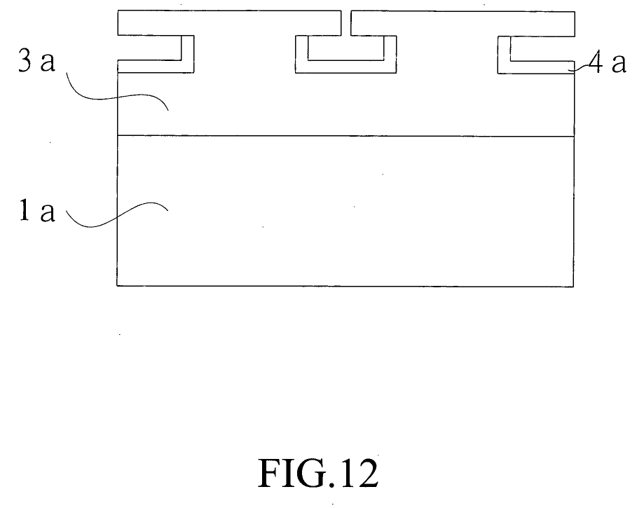

Step 4: Apply GaN pendeoepitaxy lateral overgrowth to the sample obtained after step 3 on 1000-1100 Celsius degrees of temperature. (As shown in FIG. 12)

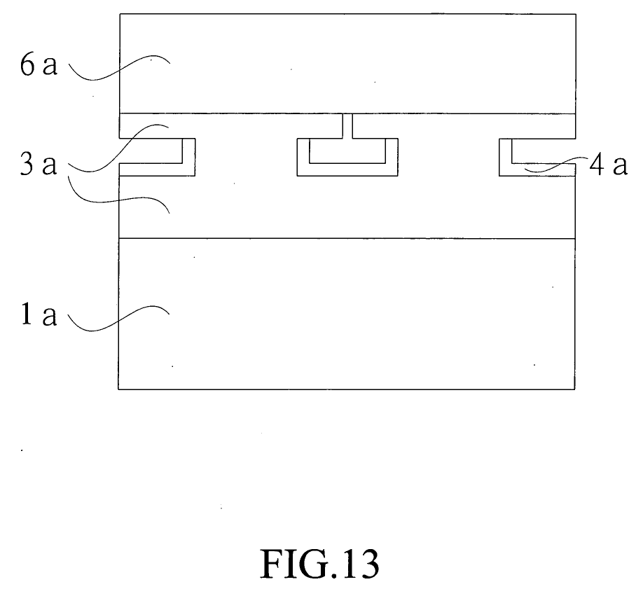

Step 5: Through proper washing and proper plating with metal like gold, indium or palladium, and so on, or plating with glue like epoxy and so on, apply wafer bonding to the sample obtained after step 4 and the substrate 6a for transference which is made of a material like Si, wherein the temperature for bonding is determined by the materials bonded and the planted material. (As shown in FIG. 13)

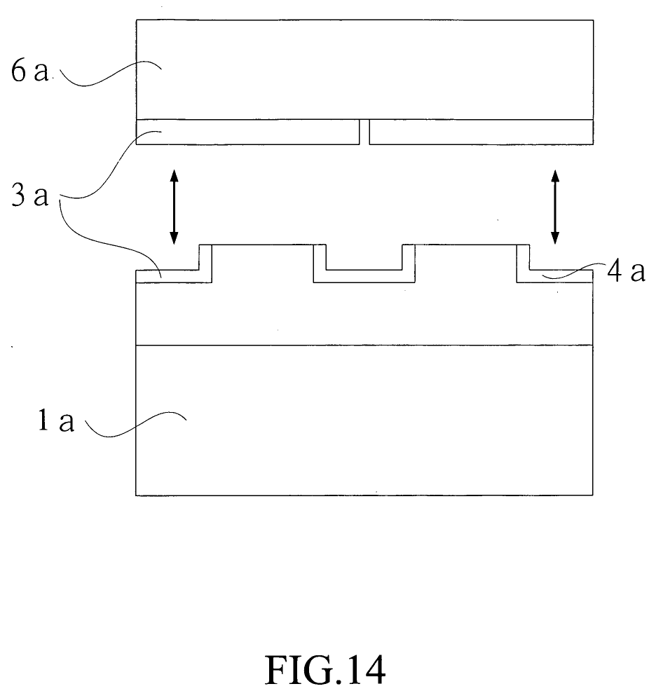

Step 6: Separate the sample obtained after step 5 from the substrate for transference. (As shown in FIG. 14)

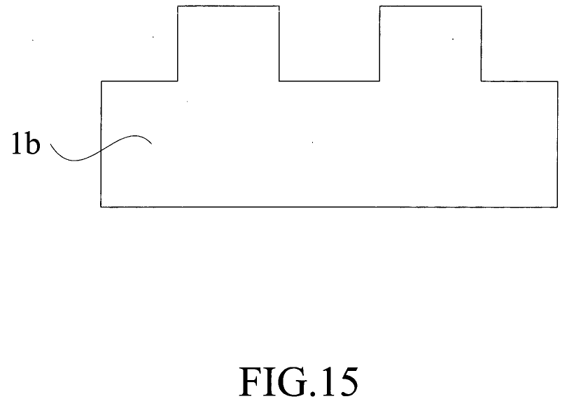

Please refer to FIG. 15 to FIG. 18, which are step 1 to step 4 of the third preferred embodiment according to the present invention. As shown in the figures, the following steps are comprised:

Step 1: Make dot pattern or line pattern on the base substrate 1b of sapphire, SiC or silicon by way of lithography technique. (As shown in FIG. 15)

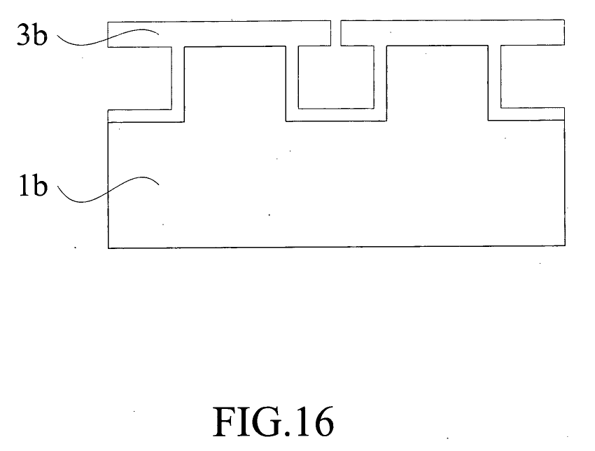

Step 2: Apply GaN 3b pendeoepitaxy lateral overgrowth to the sample of step 1 on 1000-1100 Celsius degrees of temperature. (As shown in FIG. 16)

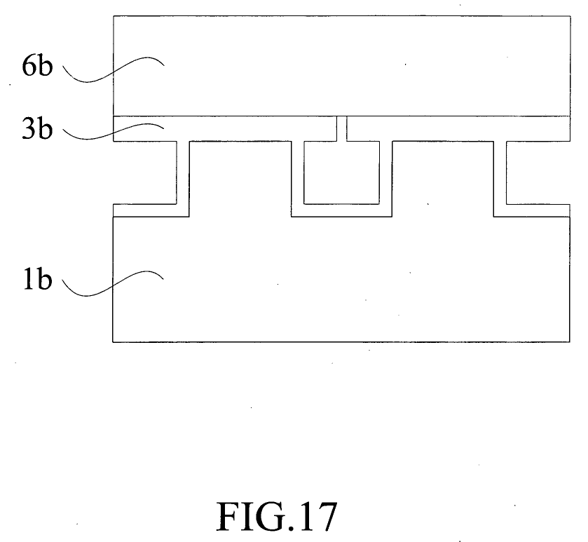

Step 3: Through proper washing and proper plating with metal like gold, indium or palladium, and so on, or plating with glue like epoxy and so on, apply wafer bonding to the sample obtained after step 2 and the substrate 6b for transference which is made of a material like Si, wherein the temperature for bonding is determined by the materials bonded and the planted material. (As shown in FIG. 17)

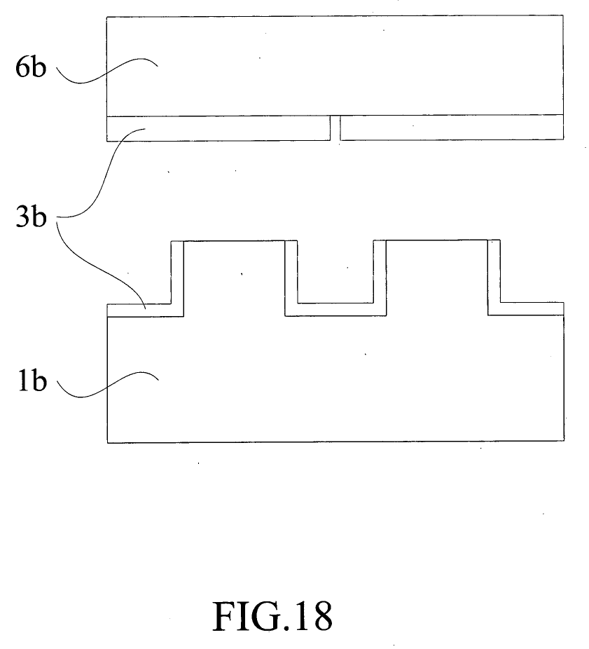

Step 4: Separate the sample obtained after step 3 from the substrate 6b for transference. (As shown in FIG. 18)

Accordingly, the present invention has the following advantages:

By wafer bonding and the procedure of obtaining GaN epitaxy layer through pseudomask epitaxy growth, GaN epitaxy layer can be transferred onto some other kinds of substrates.

The annealing of wafer bonding helps separate the epitaxy layer and the epitaxy substrate.

The epitaxy layer will not be spoiled; the cost is reduced; and large scale of size is suitable.

The epitaxy substrate separated will not be spoiled and is reusable.

There are various choices of handling substrate for bonding, not limited by the epitaxial method.

The low defect density of the epitaxy transferred can enhance the lifetime and efficiency of the devices.

No expansive equipment is required for the improved processes and so the production cost is reduced.

The GaN layer obtained by overgrowth is not directly connected with the layer of mask material, which helps the separation from the epitaxy substrate.

The area of the contact between the seed obtained by overgrowth and the layer of mask material is small, which helps separate the epitaxy layer and the epitaxy substrate on annealing.

The process for obtaining epitaxy by pseudomask overgrowth requires no wet selective etching to acquire midair structure.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

1. A method for lifting off GaN pseudomask epitaxy layer using wafer bonding way, comprising the following steps:
Step 1: To deposit a low-temperature buffer layer on a base substrate;
Step 2: To deposit a GaN layer after heating up said buffer layer;
Step 3: To deposit a layer of mask material on said buffer layer;
Step 4: To make an opening on said layer of mask material by way of lithography technique;
Step 5: To etch GaN obtained after step 4 to acquire a seed for GaN to grow upon;
Step 6: To apply GaN pendeoepitaxy lateral overgrowth to the sample obtained after etching;
Step 7: By washing as well as plating with metal, to obtain a substrate for transference to apply wafer bonding to said sample; and
Step 8: To separate said sample from said substrate for transference.

2. The method for lifting off GaN pseudomask epitaxy layer according to claim 1, wherein said base substrate is selected from a group consisting of Sapphire, SiC and Si.

3. The method for lifting off GaN pseudomask epitaxy layer according to claim 1, wherein a layer of 200-500 angstroms of low-temperature GaN or AIN is deposited on said low-temperature buffer layer on 600-700 Celsius degrees of temperature.

4. The method for lifting off GaN-pseudomask epitaxy layer according to claim 1, wherein said step 2 is done by depositing a 1.5 μm-thick GaN after the temperature is heated up to 1000-1100 Celsius degrees.

5. The method for lifting off GaN pseudomask epitaxy layer according to claim 1, wherein said layer of mask material is selected from a group consisting of SiO₂, Si₃N₄and W.

6. The method for lifting off GaN pseudomask epitaxy layer according to claim 1, wherein said opening is in a pattern selected from a group consisting of dot pattern and line pattern.

7. The method for lifting off GaN pseudomask epitaxy layer according to claim 1, wherein said GaN is obtained by pendeoepitaxy lateral overgrowth on said layer of mask material on 1000-1100 Celsius degrees of temperature.

8. The method for lifting off GaN pseudomask epitaxy layer according to claim 1, wherein said substrate for transference is made of Si.

9. The method for lifting off GaN pseudomask epitaxy layer according to claim 1, wherein the metal plated is selected from a group consisting of gold, indium and palladium.

10. The method for lifting off GaN pseudomask epitaxy layer according to claim 1, wherein the temperature for wafer bonding in said step 7 is determined by the material of said substrate for transference and the metal plated.

11. The method for lifting off GaN pseudomask epitaxy layer according to claim 1, wherein said substrate for transference is not spoiled and is reusable.

12. The method for lifting off GaN pseudomask epitaxy layer according to claim 1, wherein, during said wafer bonding in step 7, stress concentration is obtained on the contact between said base substrate and said seed to separate said base substrate and said seed owing to different thermal expansion coefficients in between.
